(19) United States
(12) Patent Application Publication
(10) Pub. No.: US 2007/0069369 A1
(43) Pub. Date: Mar. 29, 2007

(54) HEAT DISSIPATION DEVICE AND METHOD FOR MAKING THE SAME

(75) Inventors: CHUEN-SHU HOU, Tu-Cheng,Taipei Hsien (TW); CHAO-NIEN TUNG, Tu-Cheng,Taipei Hsien (TW); TAY-JIAN LIU, Tu-Cheng,Taipei Hsien (TW); CHIH-HAO YANG, Tu-Cheng,Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Taipei Hsien (TW)

(21) Appl. No.: 11/309,065

(22) Filed: Jun. 15, 2006

(30) Foreign Application Priority Data
Sep. 2, 2005 (CN) 200510037039.1

(51) Int. Cl. H01L 23/34

(52) U.S. Cl. 257/706

(57) ABSTRACT

A heat dissipation device includes a chip unit and a heat dissipation unit thermally attached to the chip unit. The chip unit includes a carrier substrate and a chip in electrical contact with the carrier substrate. The heat dissipation unit includes a heat spreader thermally contacting with the chip and a heat dissipation member coupled to the heat spreader. The heat spreader and the heat dissipation member are integrated together before they are attached to the chip unit.

### FIELD OF THE INVENTION

The present invention relates to a heat dissipation device, and more particularly relates to a heat dissipation device which has high heat dissipation efficiency and a method for making the same.

### DESCRIPTION OF RELATED ART

Higher performance, lower cost, increased miniaturization of electronic products, and greater packaging densities of integrated circuit are ongoing goals of the electronics industry. However, in achieving these goals, the heat produced by electronic components has also increased. If the temperature of the electronic component becomes too high, the electronic component may be damaged or destroyed. Thus it can be seen that advances in high science and technology have resulted in the temperature of the electronic component becoming a choke point. Therefore, designing heat dissipation devices with higher dissipation efficiency is an important challenge for the next generation of electronic products.

Various apparatus and techniques are presently being used for removing heat from electronic products. One such heat dissipation device comprises a carrier substrate, a chip and a heat spreader. The chip is attached to one side of the carrier substrate, and a plurality of pins are located on the other side of the carrier substrate, connecting the chip to a printed circuit board (PCB). The heat spreader is located at the same side as the chip, positioned so as to absorb the heat generated by the chip. An interior surface of the heat spreader contacts a top surface of the chip with a layer of heat conduction material thereon. A heat dissipation member is attached to an exterior surface of the heat spreader. Thus a heat dissipation device is formed and a fan may be incorporated into the assembly to enhance the convective heat dissipation. The heat generated by the chip is dissipated into the air surrounding the heat dissipation device. However, the contact between the heat dissipation member and the heat spreader is not perfect and an air clearance may be formed, as put the heat dissipation member on the heat spreader directly. The air clearance greatly reduces the heat transfer from the electronic products, as be understood by those skilled in the art. A thermal interface material, for example grease, is applied to the surface of the heat spreader and within the clearance, to fill up the air clearance and to increase heat dissipation efficiency.

Unfortunately, with the continuing development of electronics technology, the efficiency of heat removal is frequently not adequate for a modern electronic chip. The heat transfer coefficient of the thermal interface material, such as thermal grease is only about 2˜5 W/(m.K), that is much lower than most metals. Even if the heat dissipation capability of the heat dissipation member is improved along with increasing the airflow around the assembly, the improvement in the absolute total heat dissipation capability is limited.

It is therefore desirable to provide a heat dissipation device capable of overcoming the above mentioned problems.

### SUMMARY OF THE INVENTION

A heat dissipation device according to a preferred embodiment of the present invention comprises a chip unit and a heat dissipation unit thermally attached to the chip unit. The chip unit comprises a carrier substrate and a chip electrically contacting the carrier substrate. The heat dissipation unit comprises a heat spreader thermally contacting the chip and a heat dissipation member coupled to the heat spreader. The heat spreader and the heat dissipation member are integrated together before they are attached to the chip unit. A hermetic space is formed between the heat spreader and the carrier substrate for receiving the chip.

the advantages of this invention can be more readily ascertained from the following description of the invention when read in conjunction with the accompanying drawings, in which:

### BRIEF DESCRIPTION OF THE DRAWINGS

FIG. 1 is a cross-sectional, assembled view of a heat dissipation device in accordance with a preferred embodiment of the present invention;

FIG. 2 is a cross-sectional exploded view of the heat dissipation device of FIG. 1;

FIG. 3 is a cross-sectional assembled view of a heat dissipation device according to a second embodiment of the present invention; and

FIG. 4 is a cross-sectional assembled view of a heat dissipation device according to a third embodiment of the present invention.

### DETAILED DESCRIPTION OF THE INVENTION

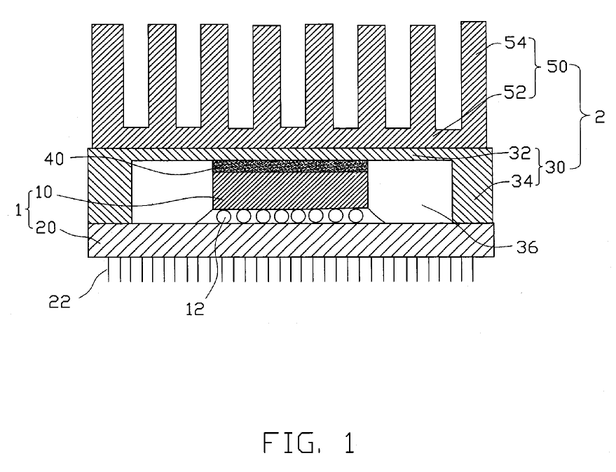

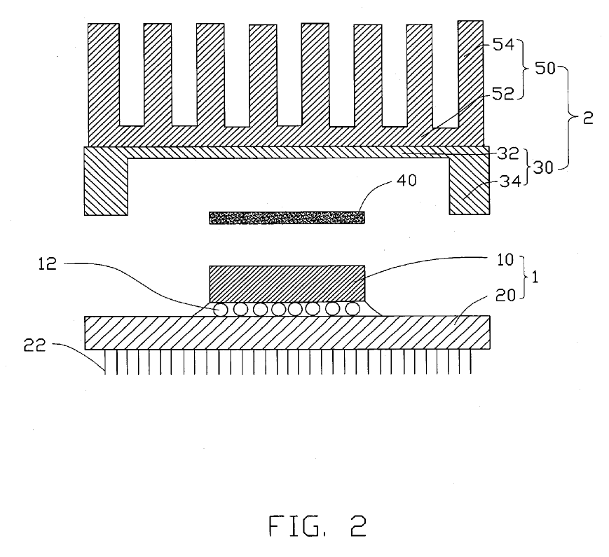

Referring to FIGS. 1-2, the heat dissipation device comprises a chip unit 1 and a heat dissipation unit 2 thermally attached to the chip unit 1. The chip unit 1 comprises a carrier substrate 20 and a chip 10 electrically contacting with the carrier substrate 20. A plurality of solder balls 12 is electrically arranged between an interior surface of the carrier substrate 20 and a bottom surface of the chip 10, thus electrically connecting the chip 10 with the carrier substrate 20. A plurality of pins 22 are formed on an exterior surface of the substrate 20 for electrically connecting with a printed circuit board (PCB) (not shown). A layer of thermal interface material 40 is spread on a top surface of the chip 10.

The heat dissipation unit 2 comprises a heat spreader 30 and a heat dissipation member, such as a heat sink 50. The heat spreader 30 may be constructed from a metallic material with a high heat transfer coefficient, such as copper, copper alloys, aluminum, aluminum alloys, and the like. In this embodiment, the heat spreader 30 is preferably made of copper. The heat spreader 30 comprises a cover portion 32 and a side portion 34 extending downwardly from a peripheral edge of the cover portion 32. A space 36 is formed between the cover portion 32 and the side portion 34 for receiving the chip 10 therein. The layer of thermal interface material 40 is spread uniformly on the top surface of chip 10 and contacts the bottom surface of the cover portion 32. The distal end of the side portion 34 hermetically connects to the interior surface of the substrate 20. Thus the space 36 is hermetically formed between the cover portion 32, the side portion 34 and the substrate 20 for hermetically enclosing the chip 10 therein.

The heat sink 50 comprises a base 52 and a plurality of fins 54 extending from the base 52. The base 52 steadily couples to the heat spreader 30 by soldering, sintering, or other known connection methods, such that the heat sink 50 and the heat spreader 30 are integrated together. The heat sink 50 and the heat spreader 30 are constructed from metallic material, such as copper and tungsten-copper alloys, of which the thermal transfer coefficients are 220 W/(m.K) and 398 W/(m.K) respectively. Thus a much better heat conduct surface between the heat spreader 30 and the heat dissipation member 50 is obtained, and the heat dissipation efficiency is increased.

Amount of heat energy produced by the chip 10 reaches to the heat sink 50 through the conduction of the heat spreader 30, and is further dissipated into the air surrounding the heat sink 50 fast. The heat dissipation efficiency is increased greatly, to ensure the chip 10 operates normally.

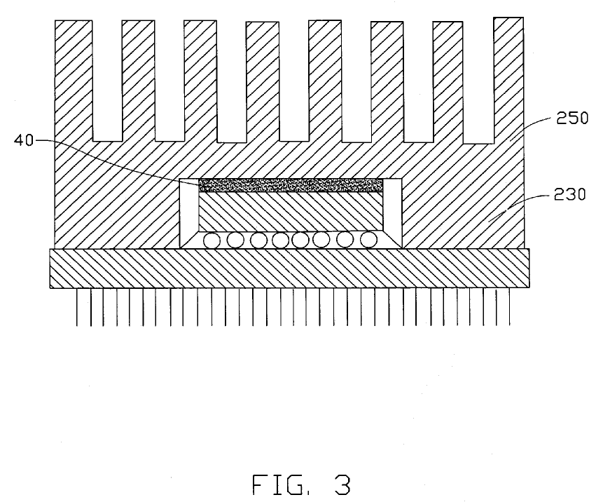

Referring to FIG. 3, it can be seen that the heat spreader 230 and the heat sink 250 are integrally formed from a same metal stock, so as to completely avoid thermal resistance existing between contacting surfaces thereof.

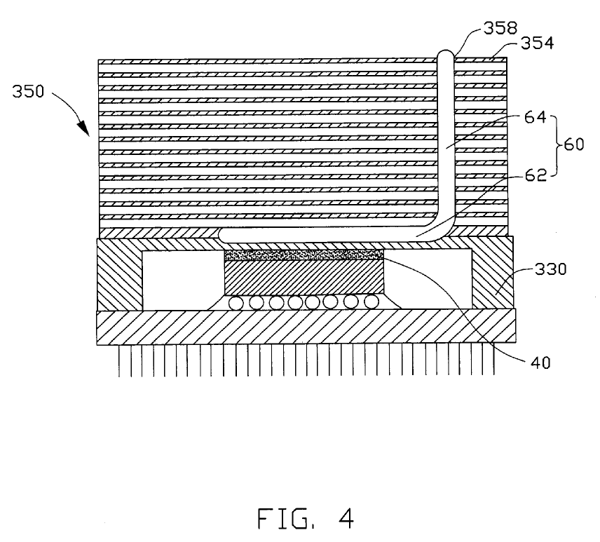

Referring to FIG. 4, the heat dissipation member 350 comprises a plurality of stacked fins 354 and a heat pipe 60 comprising an evaporation section 62 and a condensing section 64. The evaporation section 62 contacts the heat spreader 330 horizontally, and the condensing section 64 extends through the fins 354 vertically. A groove (not labeled) is formed between the heat spreader 330 and the heat sink 350 for receiving the evaporation section 62 of the heat pipe 60, and a through hole 358 is formed in each of the fins 354 for channeling the condensing section 64 of the heat pipe 60. Preferably, the evaporation section 62 of the heat pipe 60 is soldered in the groove. Understandable, the groove may also be formed only in the heat spreader 330, or in the heat sink 350 with the heat pipe 60 intimately contacting the heat spreader 330. The heat produced by the chip 10 is transferred from the heat spreader 330 to the fins 354 by the heat pipe 60, thus being further dissipated into the air surrounding the heat sink 350. The fins 354 have larger heat dissipation area, and allow heat to be dissipated evenly and more efficiently. The number of the heat pipes 60 may be adjusted according to heat dissipation requirement. The evaporation section 62 of the heat pipe 60 has a flat configuration for enlarging the contacting area between the heat pipe 60 and the heat spreader 30. The heat pipe 60 may be a loop-type heat pipe, of which one portion provides a flow-path for evaporated working fluid and the remaining portion provides a flow-path for condensed working fluid. The heat sink 350 is integrated to the heat spreader 330 by soldering or sintering before the heat spreader 330 is mounted to the carrier subsrate.

In the above described embodiments, the heat dissipation member 50, 250, 350 and the heat spreader 30, 230, 330 are integrated together without thermal interface material, for example, thermal grease or thermal tape, being spread therebetween. Thus, high thermal resistance due to thermal interface material with low heat transfer coefficient being spread between the heat dissipation member and the heat spreader as in the conventional heat dissipation devices is avoided. The heat dissipation efficiency of the heat dissipation device of the present invention is thereby enhanced.

In another aspect of the present invention, a method for making a heat dissipation device comprises the following steps: (1) providing the chip unit 1 and the heat dissipation unit 2; (2) Connecting the heat dissipation unit 2 to the chip unit 1. In the step (1), the heat spreader 30, 330 and the heat sink 50, 350 of the heat dissipation unit 2 are integrated together by soldering or sintering, as show in the first and the third embodiments of the present invention. The heat spreader 230 and the heat sink 250 may be integrally formed by, for example, molding, as shown in the second embodiment of the present invention. The heat dissipation unit 2 may further comprises the heat pipe 60 (As show in FIG. 4). In the step (2), the heat spreader 30 of the heat dissipation unit 2 is connected to the chip 10 by the layer of thermal interface material 40 applied uniformly onto the contacting surfaces. The heat dissipation unit 2 connects to the carrier substrate 20 by connecting the distal end of the side portion 34 of the heat spreader 30 to the carrier substrate 20 by soldering or gluing. The chip 10 electrically connects with the carrier substrate 20 by the plurality of solder balls 12, and is hermetically enclosed by the heat spreader 30.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation device, comprising:
a chip unit comprising a carrier substrate and a chip electrically coupled to said carrier substrate, said carrier substrate being adapted for electrically connecting with a printed circuit board; and
a heat dissipation unit comprising a heat spreader thermally coupled to the chip and contacting with the carrier substrate so as to enclose the chip between the heat spreader and the carrier substrate and a heat dissipation member thermally coupled to said heat spreader, wherein said heat spreader and said heat dissipation member are integrated together without requiring one of thermal grease and thermal tape to be spread therebetween before they are coupled to said chip.

2. The heat dissipation device of claim 1, wherein said heat dissipation member and said heat spreader integrate together by one of soldering and sintering.

3. The heat dissipation device of claim 1, wherein said heat dissipation member and said heat spreader are integrally formed from a same metal stock.

4. The heat dissipation device of claim 1, wherein said heat spreader comprises a cover portion and a side portion extending downwardly from a peripheral edge of said cover portion, and a hermetic space for receiving said chip is formed between said heat spreader and said carrier substrate.

5. The heat dissipation device of claim 1, wherein said heat dissipation member comprises a base coupled to said heat spreader and a plurality of fins extending from said base.

6. The heat dissipation device of claim 5, wherein said heat dissipation member comprises a heat pipe which comprises an evaporation section thermally coupling to said heat spreader and a condensing section extending through the fins.

7. The heat dissipation device of claim 6, wherein a groove for receiving said evaporation section of said heat pipe is formed in said heat spreader, said evaporation section being fixed in said groove by soldering.

8. The heat dissipation device of claim 6, wherein said evaporation section of said heat pipe has a flat shape.

9. The heat dissipation device of claim 6, wherein said heat pipe is a loop-type heat pipe.

10. A method for making a heat dissipation device, comprising the following steps:
providing a heat dissipation unit comprising a heat spreader and a heat dissipation member integrated together, the heat dissipation member comprising a plurality of fins;
providing a chip unit comprising a carrier substrate and a chip electrically contacting with said carrier substrate; and
connecting said chip unit and said heat dissipation unit, wherein said chip thermally connects to said heat spreader, said carrier substrate hermetically connects to said heat spreader thereby forming a hermetic space to enclose said chip therein.

11. The method of claim 10, wherein said heat dissipation member couples to said heat spreader by one of soldering and sintering.

12. The method of claim 10, wherein said heat spreader couples to the heat dissipation member before said heat spreader hermetically connects to said carrier substrate.

13. The method of claim 10, wherein said heat spreader comprises a cover portion and a side portion extending downwardly from said cover portion, said hermetic space being formed by said cover portion, said side portion and said substrate.

14. The method of claim 10, wherein said heat dissipation member comprises a base coupling to said heat spreader and the plurality of fins extending from said base.

15. The method of claim 10, wherein a groove is formed in said heat spreader.

16. The method of claim 10, wherein said heat dissipation unit further comprise a heat pipe being fixed in said groove by soldering.

17. The method of claim 10, wherein said heat dissipation member and said heat spreader are integrally formed from a same metal stock.

18. A method for manufacturing an electronic package comprising:
providing a carrier substrate having a top surface and a bottom surface adapted for being electrically connected to a printed circuit board, a chip being mounted on the top surface of the carrier substrate;
providing a heat spreader having a heat sink integral thereon;
mounting the heat spreader to the top surface of the carrier substrate with the heat spreader thermally connecting with the chip and hermetically enclosing the chip.

19. The method of claim 18, wherein the heat sink is integral on the heat spreader by one of soldering and sintering.

20. The method of claim 19, wherein a thermal interface material is located between the chip and the heat spreader.
